(19) United States
(12) Patent Application Publication
(10) Pub. No.: US 2020/0266781 A1
(43) Pub. Date: Aug. 20, 2020

(54) AMPLIFIER CIRCUIT, CORRESPONDING SYSTEM, VEHICLE AND METHOD

(71) Applicant: STMicroelectronics S.r.l., Agrate Brianza (MB) (IT)

(72) Inventors: Alessandro FINOCCHIARO, Catania (IT); Giuseppe PAPOTTO, Biancavilla (CT) (IT); Egidio RAGONESE, Aci Catena (CT) (IT); Giuseppe PALMISANO, S. Giovanni La Punta (CT) (IT)

(73) Assignee: STMicroelectronics S.r.l., Agrate Brianza (MB) (IT)

(21) Appl. No.: 16/793,144

(22) Filed: Feb. 18, 2020

(30) Foreign Application Priority Data
Feb. 20, 2019 (IT) 102019000002449

(51) Int. Cl. H03F 3/45; H03F 1/34; H04B 1/40; B60R 11/02; B60R 11/04; B60R 16/023

(52) U.S. Cl. CPC H03F 3/45179; H03F 1/342; H04B 1/40; B60R 11/02; B60R 11/04; B60R 16/023; H03F 2203/45212; H03F 2200/129; H03F 2200/144; H03F 2203/45114; H03F 2203/45116; H03F 2203/45526; H03F 2200/375

(57) ABSTRACT

A cascade of amplifier stages has a differential input and a differential output. The cascade of amplifier stages includes at least one differential amplifier circuit including first and second transistors, at least one of the first and second transistors having a control terminal and a body terminal. A mismatch between the first and second transistors generates an input offset. A feedback network couples the differential output to the body terminal in order to cancel the input offset. The feedback network includes a low-pass filter and a differential amplifier stage.

### PRIORITY CLAIM

This application claims the priority benefit of Italian Application for Patent No. 102019000002449, filed on Feb. 20, 2019, the content of which is hereby incorporated by reference in its entirety to the maximum extent allowable by law.

### TECHNICAL FIELD

The present description relates to an amplifier circuit, for example, a Variable-Gain Amplifier (VGA) circuit. One or more embodiments may be used, for example, in automotive radar sensor applications.

### BACKGROUND

Increasingly higher demand for driving safety standards has led to a widespread adoption of Advanced Driver Assistance System (ADAS) in the automotive field.

ADAS implement control systems which may exploit several sensors, for example, radar sensors, to provide functionalities such as adaptive cruise control, collision-avoidance, park assist, etc.

A vehicle may include a plurality of radar sensors to facilitate detecting the position and speed of objects nearby. For instance, such radar sensors may operate by transmitting a signal, for example, a mm-wave signal (24/77 GHz according to the ETSI standard), and receiving an echo signal reflected by the object nearby.

Distance and speed of the object are detected by measuring a time delay between a transmitted signal and the received echo signal.

Radar sensors in a vehicle (or vehicular radar sensors) may employ amplifier circuits, for instance for amplifying received echo signals.

For example, a Variable-Gain Amplifier (VGA) circuit may be included to process baseband signals of the radar sensor.

A VGA, like many amplifier circuits, may suffer from an input offset voltage problem, which can compromise the VGA operation.

As exemplified in FIG. 1, an amplifier circuit block 10 may be modeled as a differential amplifier stage 14 having a non-inverting input Vᵢₙ⁺ coupled to an offset-voltage generator Vos (modeling the parasitic input offset voltage) having a voltage Vₒₛ thereacross; an inverting input Vᵢₙ⁻; and an output node Vₒᵤₜ where the amplified voltage Vₒᵤₜ may be provided to user circuits.

Input Offset Voltage Vos is defined as the voltage that, once applied to the input, makes the output equal to ground (for example, zero Volts). The polarity of this voltage Vₒₛ is arbitrary and depends on manufacturing parameters and spreads. As mentioned, the offset is modeled by a single voltage source Vos placed in series with one of the inputs, for example, the non-inverting input Vᵢₙ⁺.

Offsets Vₒₛ may arise from input stage mismatch and cause the input-output Vᵢₙ-Vₒᵤₜ characteristic to shift in either the positive or negative direction (as exemplified in FIG. 2 for the positive direction).

As exemplified in FIG. 2, the output voltage Vₒᵤₜ may be expressed as a function of the input voltage drop Vᵢₙ, for example, Vᵢₙ=Vₒₛ+Vᵢₙ⁺−Vᵢₙ⁻.

As a result of the offset voltage parasitic effect, the output of the amplifier depends on the offset voltage level, for example, Vₒᵤₜ=(Vᵢₙ⁺−Vᵢₙ⁻)*A+Vₒₛ*A, degrading the performance of the amplifier circuit 14.

Indeed, even a small dc offset voltage Vos can be amplified by the amplifier 14 to a level that may saturate cascading stages and/or may cause the output signal to be clipped.

If the offset input voltage is not addressed, drawbacks may include accuracy errors and output saturation.

Typical offset voltages Vos values go from a few V to tens of mV.

In CMOS technology, the offset of a differential input pair can be as large as 10 mV. This offset is caused by manufacturing variation or uncertainty.

For example, MOS devices exhibit threshold voltage (often indicated with the symbol Vₜₕ) mismatch because Vₜₕ is a function of the doping levels in MOS channels and the gates, and these parameters may vary randomly from one device to another. On the other hand, the dimensions of MOS devices suffer from random, microscopic variations during fabrication and hence there is mismatch between the equivalent lengths and widths of nominally identical transistors. This mismatch can be reduced by using large devices. However, this increases chip area and therefore production cost.

In a VGA architecture, where multiple amplification stages may be cascaded, such an effect can be very detrimental. Hence, offset compensation is a figure of merit to guarantee VGA operation.

Known approaches to addressing input offset voltages include:
trimming, which may be applied during VGA production and may utilize an offset measurement; it presents the drawbacks, among others, of providing a coarse offset reduction without providing the possibility to compensate eventual offset values drifts;
auto-zeroing circuits, which may facilitate dynamic cancellation of the offset voltage; they present the drawbacks, among others, of reducing the amplifier bandwidth, thus degrading its phase margin and stability, and affecting the amplifier's noise performance at frequencies below the sampling frequency;
chopping techniques, which may be more effective; they present the drawbacks, among others, of employing high circuit complexity and giving rise to a chopper ripple at the amplifier output.

U.S. Pat. No. 8,400,337 discusses an offset canceled approach by determining a voltage level to which a body input of a transistor is set. This approach includes using a digital calibration engine to set the bodies of transistors by a calibration phase. The digital calibration circuits may include controller, ADC, clock, and other circuits. The accuracy depends on calibration engine capability.

United States Patent Application Publication No. 2017/0155386 discusses an apparatus including a first field effect transistor (FET) and a second FET having bodies coupled in a circuit. The circuit has an offset because of a mismatch, and an offset correction circuit is coupled to the bodies of the first and second FET. The offset correction circuit provides a first offset correction signal to the body of the first FET and a second offset correction signal to the body of the second FET. This approach also involves a calibration phase and poses constraints on providing matched transistors among the correction circuit and FETs; also, it discusses an open loop approach.

Despite the extensive activity in this area, as witnessed by various documents discussed in the foregoing, further improvements are desirable.

There is accordingly a need in the art to contribute in providing such improvements.

### SUMMARY

An embodiment concerns an amplifier circuit for dynamic offset compensation via negative (closed loop) feedback on body bias. This circuit may be used in a number of arrangements (for example, a radar sensor). A receiver may further employ such a voltage gain amplifier circuit for automotive radar applications. The amplifier may be used in a vehicular radar sensor system.

One or more embodiments may relate to a corresponding vehicle, for instance a vehicle equipped with a circuit and/or a system according to embodiments described herein.

One or more embodiments may relate to a corresponding method.

In an embodiment, an amplifier circuit has a cascade of amplifier stages with a differential input and an output and includes at least one differential amplifier circuit with first and second transistors. The first and second transistors in the at least one differential amplifier circuit may include at least one transistor having a control terminal and a body-terminal. The first and second transistors may have a mismatch therebetween which generates an input offset. A feedback network includes a low-pass filter and a differential amplifier stage, wherein the feedback network forms a feedback loop of the signal at the output. The feedback loop includes the differential amplifier stage in the feedback network coupled to the body terminal of the at least one transistor in the pair of transistors.

In one or more embodiments, the at least one transistor in the pair of transistors in the at least one differential amplifier circuit block may be a FD-SOI transistor, preferably a 28 nm technology FD-SOI transistor.

One or more embodiments may adopt a negative feedback closed loop approach, facilitating correction of both the input voltage offset value and its dynamic drift value, the latter being caused, for example, by temperature variation or aging.

In one or more embodiments, the first transistor and the second transistor may have respective control terminals and body-terminals, and the differential amplifier stage in the feedback network may be coupled to the body terminal of the first and second transistor in the pair of transistors.

One or more embodiments may exploit body-effect phenomenon and negative feedback architecture to reduce mismatch between transistors in the differential amplifier.

One or more embodiments may facilitate reducing circuital complexity.

In one or more embodiments, amplifier noise figure may be maintained or improved without compromising amplifier performance.

One or more embodiments may eliminate or render redundant a compulsory calibration phase (or trimming) during the manufacturing/testing/operation phases.

One or more embodiments may be directed to a fully-analog offset compensation circuit arrangement.

In one or more embodiments, the feedback loop formed by the feedback network across the cascade of amplifier stages may have a closed loop gain value configured to zero-out the offset component.

One or more embodiments may facilitate an accurate offset cancellation by setting a closed loop gain value.

One or more embodiments may include a system (for example, a transceiver) with at least one antenna, and at least one receiver and/or transmitter circuit arrangement coupled to the at least one antenna. Such a system includes at least one circuit according to one or more embodiments.

In one or more embodiments, the corresponding method may include forming a feedback loop across the output port and the input port in a cascade of amplifier stages via a feedback network by varying a threshold voltage in at least one of first and second transistors via their respective control terminals and provide as output an amplified voltage signal.

### BRIEF DESCRIPTION OF THE DRAWINGS

One or more embodiments will now be described, by way of non-limiting example only, with reference to the annexed Figures, wherein:

FIG. 1 shows a model of an amplifier circuit block;

FIG. 2 shows a graphic representation of the voltage offset;

FIG. 3 is a diagram of an amplifier circuit;

FIG. 4 is exemplary of a two-gated transistor model;

FIG. 5 is a diagram of an amplifier circuit; and

FIG. 6 shows a receiver arrangement and vehicle.

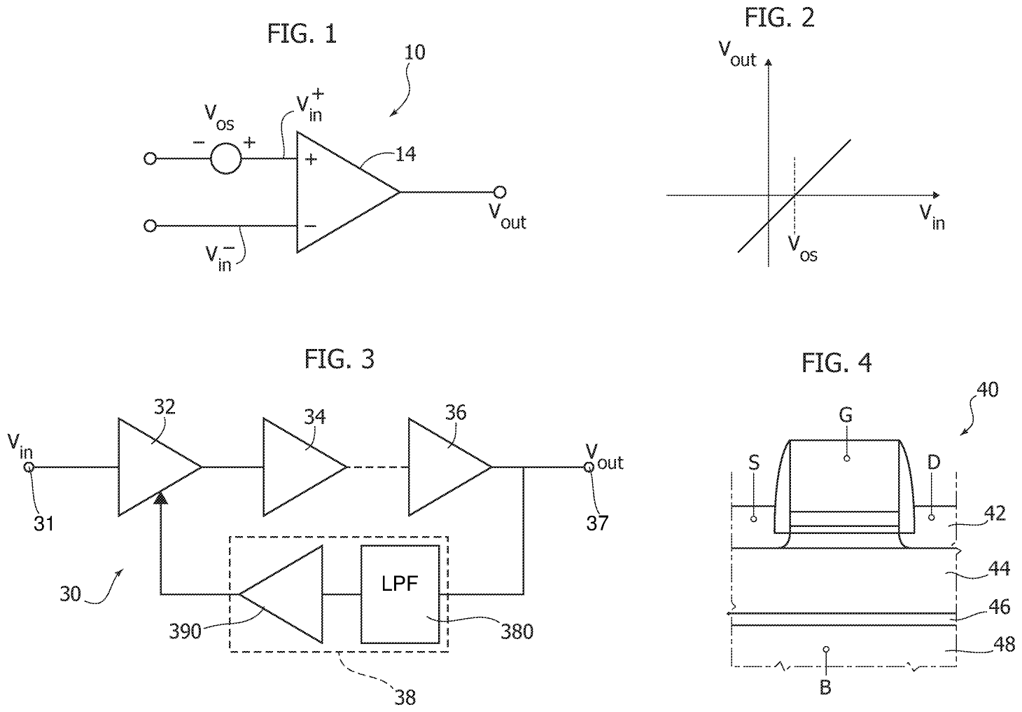

### DETAILED DESCRIPTION

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The references used herein are provided merely for convenience and hence do not define the extent of protection or the scope of the embodiments.

The Inventors have observed that employing a negative feedback loop may be suitable for use in one or more embodiments. Specifically, the output variable of the system is read by the feedback network, which acts by modifying the input of the system. It may continuously calculate an error value as the difference between a target value and a measured value, and apply a respective correction, for example, automatically apply accurate and responsive correction to a control function.

As exemplified in FIG. 3, in one or more embodiments an amplifier circuit 30 with an offset voltage compensation feedback loop may comprise:
an input node 31,
a cascade of amplifier stages 32, 34, 36, comprising a first amplifier stage 32, a second amplifier stage 34, and a third amplifier stage 36,
an output node 37,
an Offset Compensation (OC) stage 38, which may comprise a low-pass filter (LPF) stage 380 and a feedback amplifier stage 390, as discussed in the following.

For the sake of simplicity, the cascade of amplifier stage 32, 34, 36 discussed in the following comprises three amplifiers in the example considered, it being otherwise understood that such a quantity is purely exemplary and in no-way limiting.

In one or more embodiments, the first amplifier stage may comprise one or more transistors which may be operated with two control terminals.

Typically, a transistor is modeled or represented as having three terminals (for example, a gate, a drain and a source, although other types of transistors may use different terms) and those inputs are coupled to other nodes in the system.

One or more transistors as per the present disclosure may comprise a fourth terminal (for example, the body input, also referred to as back-gate or body terminal) which is coupled to a node in the system.

As exemplified in FIG. 4, a two-gated transistor 40 may comprise a front gate (or control terminal), for example, a gate control terminal G, and a back-gate (or body terminal) B, for example, a body control terminal B, which may be operated to perform so-called body biasing, for example, for power and speed scaling, facilitating modification of the transistor threshold voltages.

Body biasing is beneficial in that it enables trade off digital circuit performance in exchange for control of the threshold voltage, for example, by about 80 mV through a variation of the voltage of 1 V applied to the back-gate B.

Body biasing may facilitate employment of smaller transistors in the circuit 30, which may make it faster and reduce its area footprint.

For instance, one or more Fully Depleted Silicon-On-Insulator (FD-SOI) MOSFET transistors, for example, 28 nm CMOS technology transistors, may be employed in the circuit 30.

As exemplified in FIG. 4, a semiconductor device (MOSFET) such as a SOI MOSFET 40 may comprise an insulator layer 44, which may be a buried oxide (BOX) layer formed in a semiconductor substrate, and a semiconductor layer 42, for example, of silicon Si or germanium Ge, formed thereon.

In the considered example, the four pins or terminals of the transistor in diagram 40 are source S, front gate (or gate or control terminal) G, drain D and body terminal (or back-gate) B. A threshold voltage value to turn on a signal path between drain D and source S terminals may be indicated as Vₜₕ.

For an n-type FDSOI MOSFET as exemplified in FIG. 4, the sandwiched p-type film 42 between the gate oxide (GOX) and buried oxide (BOX) may be very thin, so that the depletion region covers the whole p-region film. In the considered example, front gate (or control terminal) G may support fewer depletion charges than back gate B so an increase in inversion charges occurs, for example, resulting in higher switching speeds.

In one or more embodiments, the limitation of the depletion charge by the BOX may induce a suppression of the depletion capacitance and therefore a substantial reduction of the subthreshold swing, for example, facilitating FDSOI MOSFETs to work at lower gate bias resulting in lower power operation.

In one or more embodiments, the employ of FDSOI MOSFET technology may reduce drawbacks with respect to bulk MOSFETs, for instance threshold voltage roll off, since source and drain electric fields can't interfere as a result of the BOX layer.

In any case, any other type of transistor technology having a front control terminal and a bulk/body terminal for controlling the threshold voltage may be employed, for example MOSFETs, FETs, etc.

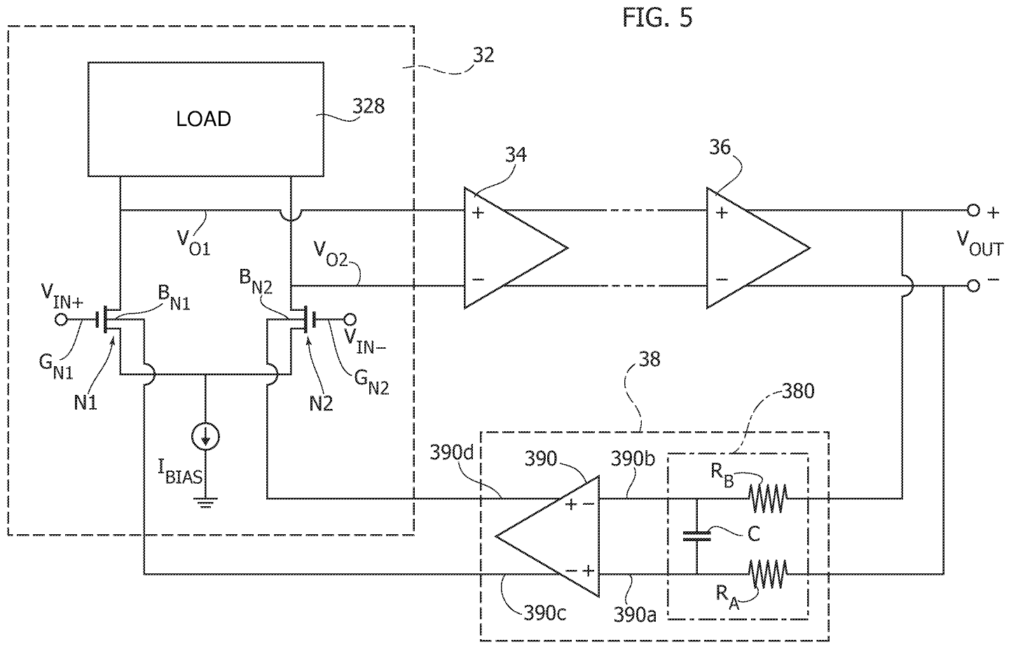

In one or more embodiments as exemplified in FIG. 5, the first amplifier stage 32 in the cascade of amplifier stages 32, 34, 36 may comprise:
a first N1 and second N2 transistor, having respective gate G_{N1}, G_{N2} and body B_{N1}, B_{N2} terminals and coupled as a differential pair having input nodes V_{IN+}, V_{IN-} at respective gate nodes G_{N1}, G_{N2} and output nodes V_{O1}, V_{O2} at respective drain nodes,
a bias current generator I_{BIAS} coupled to common source nodes in the first and second transistors N1, N2, and
a load 328 coupled to respective drain nodes in the first and second transistors N1, N2, for example, comprising, for example, a resistive load to adjust an optimum bias voltage in the differential coupled transistors N1, N2.

In one or more embodiments as exemplified in FIG. 5, the low-pass LP filter 380 in the offset compensation circuit block 38 may comprise a capacitor C coupled in series between a pair of resistors, R_{A}, R_{B}.

In one or more embodiments, the feedback amplifier stage in the offset compensation stage 38 may comprise a differential amplifier stage 390 having a non-inverting input 390a, an inverting input 390b, an inverting output node 390c and an inverting output node 390d, wherein output nodes are coupled to respective back-gate nodes B_{N1}, B_{N2} in respective transistors N1, N2 in the differential pair N1, N2 in the first amplifier stage 32. For instance:
the inverting output node 390c may be coupled to the back-gate node B_{N1} in the first transistor N1, and
the non-inverting output node 390d may be coupled to the back-gate node B_{N2} in the second transistor N2.

As mentioned, the Offset Compensator (OC) circuit block 38 may be arranged in a negative feedback loop between output V_{OUT} of the amplifier cascade 32, 34, 36 and nodes input V_{N+}, V_{IN-} of the differential pair N1, N2 in the first amplifier stage 32 in the amplifier cascade.

As a result, voltage correction may be provided to the transistors N1, N2 of the input differential amplifier by means of the output (offset) voltage acquired by the OC block 38.

Consequently, offset compensation 38 may be performed the to properly induce a variation of threshold voltage Vₜₕ of the two transistors N1, N2 of the input differential stage 32 by exploiting the body effect in transistors in the differential coupled transistors N1, N2, thus cancelling the input offset voltage Vₒₛ as discussed in the following.

The body effect upon transistor signal path channel can be described as a modification of the threshold voltage Vₜₕ which may be expressed as:

Vₜₕ=Vₜₕ₀+γ(\sqrt{|−φ_{B}+V_{SB}|}−\sqrt{|2φ_{B}|})

where:
Vₜₕ is the threshold voltage with substrate bias present,
Vₜₕ₀ is the zero-V_{SB} value of threshold voltage (V_{SB} indicating source to body voltage),

$$- γ = \frac{\sqrt{2 q {N}_{A} {ɛ}_{Si}}}{{C}_{OX}} is the body effect parameter ,$$

and
2φ_{B} is the approximate potential drop between surface and bulk across the depletion layer when V_{SB}=0 and the gate bias is sufficient to ensure that a channel is present.

For instance, the threshold voltage of a MOSFET may be affected by the voltage which is applied to the body/back contact B. The voltage difference between the source and the bulk, V_{SB} changes the width of the depletion layer and therefore also the voltage across the oxide due to the change of the charge in the depletion region, resulting in a difference in threshold voltage which equals the difference in charge in the depletion region divided by the oxide capacitance.

In one or more embodiments as exemplified in FIG. 5, amplifier stage 32, 34, 36 may have a respective gain value associated to the stage, for instance:
a first gain value A₁ for the first amplifier stage 32,
a second gain value A₂ for the second amplifier stage 34,
a third gain value A₃ for the third amplifier stage 36, and so on.

Thus, a total gain T may be obtained for the amplifiers cascade which may be expressed as the product of respective gains, for example: T=A₁*A₂*A₃.

If the input voltage offset Vos is present at the input nodes V_{N+}, V_{IN-}, this offset may be amplified by the total gain T providing an (output) offset voltage Vₒₛ′ having approximately a value of, for example: Vₒₛ′=T*Vₒₛ.

In one or more embodiments, as a result of a negative closed loop via the feedback amplification stage 380, the offset voltage at the input Vₒₛ can be reduced to a negligible value, for example, by modifying the total loop gain from the open loop value T to a closed loop value T′ taking into account also a respective gain value β of the amplifier in the feedback branch 380, for instance: T′=T/(1+β).

Said otherwise, the offset compensator 38 exploits the (output) offset voltage Vos' to control the MOS transistors N1, N2 of the first differential amplifier 32 of the VGA 30.

In one or more embodiments, the offset compensator 38 may use the Low-Pass Filter (LPF) 380 to safeguard the lower band of the VGA amplifier/regulator 30.

In one or more embodiments, the offset compensator 38 may use the LPF 380 to provide a suitable closed loop gain, for example, when the total gain T given by the main gain chain 32, 34, 36 is very high.

It is noted that the proposed circuit can be integrated in any circuit/functional block that suffers from voltage offset, not only in a VGA but also in other contexts such as operational amplifiers, regulators, etc.

In one or more embodiments, different transistor technologies can be applied, for example CMOS, FET, MOSFET, etc.

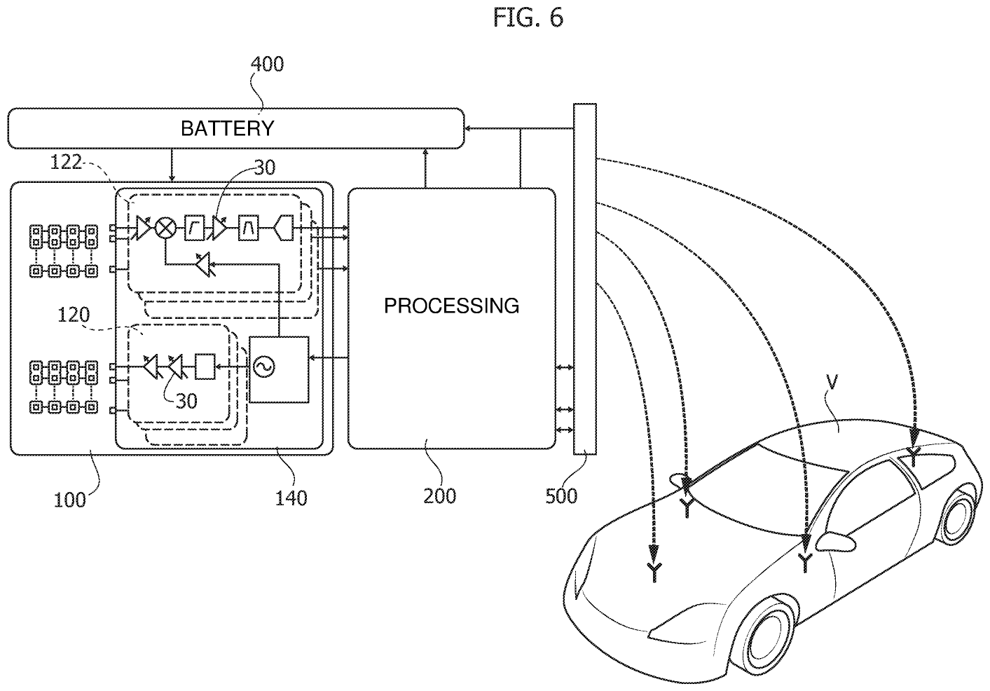

One or more embodiments as exemplified in FIG. 6, may be employed to cancel the offset voltage Vos from a variable-gain amplifier (VGA) circuit 110, 112 used in the baseband of a radar receiver 122 or transmitter 120, for example, a 77 GHz CMOS radar transceiver 140.

In one or more embodiments the system 100 may have further processing stages 200 and communication interfaces 500 and a battery 400 to provide power supply circuits in the system 100.

For instance, the radar sensor system 100 in the vehicle V may provide support to a vehicle driver, for example, via an Automated Driving Assistance System ADAS capable to take control over the vehicle, in detecting people crossing the road during the night or in adverse eye visibility conditions, hence facilitating a reduction in the number of road accidents.

For instance, in such an application context, one or more embodiments may advantageously avoid potential saturation of the output level even with a small input offset voltage.

For instance, one or more embodiments may employ 28 nm FDSOI CMOS technology, facilitating voltage to control of the threshold voltage Vₜₕ through the body terminal (or back-gate), for example, by about 80 mV/V (1 mV=1 milliVolt=10⁻³ Volt).

It will be otherwise understood that the various individual implementing options exemplified throughout the figures accompanying this description are not necessarily intended to be adopted in the same combinations exemplified in the figures. One or more embodiments may thus adopt these (otherwise non-mandatory) options individually and/or in different combinations with respect to the combination exemplified in the accompanying figures.

Without prejudice to the underlying principles, the details and embodiments may vary, even significantly, with respect to what has been described by way of example only, without departing from the extent of protection. The extent of protection is defined by the annexed claims.

1. A circuit, comprising:
a cascade of amplifier stages having a differential input and a differential output, each amplifier stage comprising at least one differential amplifier circuit comprising first and second transistors, wherein the first and second transistors in the at least one differential amplifier circuit:
a) comprise at least one transistor having a control terminal and a body terminal, and
b) have a mismatch therebetween which generates an input offset; and
a feedback network comprising a low-pass filter and a differential amplifier stage;
wherein the feedback network forms a feedback loop for a signal at said differential output;
wherein the differential amplifier stage in the feedback network receives the signal at said differential output as input and is coupled to the body terminal of the at least one transistor to bias the body terminal; and
wherein the low-pass filter comprises:
a first resistor having a first terminal coupled to a first node of the differential output and a second terminal coupled to a first input of the differential amplifier stage,
a second resistor having a first terminal coupled to a second node of the differential output and a second terminal coupled to a second input of the differential amplifier stage, and
a capacitor having a first terminal coupled to the second terminal of the first resistor and a second terminal coupled to the second terminal of the second resistor.

2. The circuit of claim 1, wherein:
the first transistor and the second transistor have respective control terminals and body terminals, and
the differential amplifier stage in the feedback network is coupled to the body terminals of the first and second transistors.

3. The circuit of claim 1, wherein the feedback loop formed by the feedback network across the cascade of amplifier stages has a closed loop gain value configured to zero-out the input offset.

4. The circuit of claim 1, wherein the at least one transistor of the first and second transistors having the control terminal and the body terminal is a FD-SOI transistor.

5. The circuit of claim 1, wherein the at least one transistor of the first and second transistors having the control terminal and the body terminal is a 28 nm technology FD-SOI transistor.

6. A system, comprising:
at least one antenna, and
at least one receiver or transmitter circuit arrangement, coupled to the at least one antenna and comprising at least one amplifier circuit, the at least one amplifier circuit comprising:
a cascade of amplifier stages having a differential input and a differential output, each amplifier stage comprising at least one differential amplifier circuit comprising first and second transistors, wherein the first and second transistors in the at least one differential amplifier circuit:
a) comprise at least one transistor having a control terminal and a body terminal, and
b) have a mismatch therebetween which generates an input offset; and
a feedback network comprising a low-pass filter and a differential amplifier stage;
wherein the feedback network forms a feedback loop for a signal at said differential output;
wherein the differential amplifier stage in the feedback network receives the signal at said differential output as input and is coupled to the body terminal of the at least one transistor to bias the body terminal; and
wherein the low-pass filter comprises:
a first resistor having a first terminal coupled to a first node of the differential output and a second terminal coupled to a first input of the differential amplifier stage,
a second resistor having a first terminal coupled to a second node of the differential output and a second terminal coupled to a second input of the differential amplifier stage, and
a capacitor having a first terminal coupled to the second terminal of the first resistor and a second terminal coupled to the second terminal of the second resistor.

7. The system of claim 6, wherein the system is configured to define a transceiver.

8. The system of claim 6, wherein the system is configured to define a vehicular radar system.

9. The system of claim 6, wherein the at least one transistor of the first and second transistors having the control terminal and the body terminal is a FD-SOI transistor.

10. The system of claim 9, wherein the at least one transistor of the first and second transistors having the control terminal and the body terminal is a 28 nm technology FD-SOI transistor.

11. The system of claim 8, wherein the vehicular radar sensor system is a component of a vehicle.

12. A method, comprising:
amplifying a differential input signal through a cascade of amplifier stages to generate a differential output signal;
where at least one amplifier stage includes a differential amplifier circuit comprising a first and second transistors, at least one of the first and second transistors having a control terminal and body terminal, and wherein a mismatch between the first and second transistors generates an input offset;
low-pass filtering the differential output signal to generate a filtered differential signal;
differentially amplifying the filtered differential signal to generate a feedback control signal;
applying the feedback control signal to the body terminal of said at least one of the first and second transistors varying a threshold voltage to vary a threshold voltage of said at least one of the first and second transistors and cancel the input offset.

13. The method of claim 12, further comprising selecting a closed loop gain value in order to zero-out said input offset.

14. A circuit, comprising:
a cascade of amplifier stages having a differential input and a differential output, at least one of the cascade of amplifier stages comprising first and second transistors having control terminals and having body terminals, wherein the first and second transistors have a mismatch therebetween which generates an input offset; and
a feedback network coupled between the differential output and the body terminals, the feedback network comprising a low-pass filter and a differential amplifier stage, the differential amplifier stage generating a control signal applied to the body terminal of the first transistor to cancel the input offset;
wherein the low-pass filter comprises:
a first resistor having a first terminal coupled to a first node of the differential output and a second terminal coupled to a first input of the differential amplifier stage,
a second resistor having a first terminal coupled to a second node of the differential output and a second terminal coupled to a second input of the differential amplifier stage, and
a capacitor having a first terminal directly connected to the second terminal of the first resistor and a second terminal directly connected to the second terminal of the second resistor.

15. The circuit of claim 14, wherein the first and second transistors are coupled in parallel between a load and a bias current generator.

16. The circuit of claim 14, wherein a feedback loop formed by the feedback network across the cascade of amplifier stages has a closed loop gain value configured to zero-out the input offset.

17. The circuit of claim 14, wherein the first and second transistors are FD-SOI transistors.
